(19) United States
(12) Patent Application Publication
(10) Pub. No.: US 2026/0213526 A1
(43) Pub. Date: Jul. 23, 2026

(54) ELECTROSTATIC DISCHARGE PROTECTION DEVICE

(71) Applicant: AMAZING MICROELECTRONIC CORP., New Taipei City (TW)

(72) Inventors: Kun-Hsien LIN, Hsinchu City (TW); Zi-Ping CHEN, New Taipei City (TW); Sin-Ping HUANG, New Taipei City (TW)

(73) Assignee: AMAZING MICROELECTRONIC CORP., New Taipei City (TW)

(21) Appl. No.: 19/034,070

(22) Filed: Jan. 22, 2025

(51) Int. Cl. H02H 9/02

(52) U.S. Cl. CPC H02H 9/02

(57) ABSTRACT

An electrostatic discharge protection device includes a triggering bipolar junction transistor and a silicon-controlled rectifier coupled between a first conduction pad and a second conduction pad. The triggering bipolar junction transistor has a first parasitic base-emitter resistance. The silicon-controlled rectifier includes a first parasitic bipolar junction transistor and a second parasitic bipolar junction transistor. The emitter and the base of the second parasitic bipolar junction transistor are respectively coupled to the emitter and the base of the triggering bipolar junction transistor. The second parasitic bipolar junction transistor has a second parasitic base-emitter resistance less than the first parasitic base-emitter resistance. The collector of the triggering bipolar junction transistor is implemented with a first heavily doped area. The base of the first parasitic bipolar junction transistor is implemented with a first doped region that separates from the first heavily doped area.

### BACKGROUND OF THE INVENTION

### Field of the Invention

The present invention relates to a protection device, particularly to an electrostatic discharge protection device.

### Description of the Related Art

As the IC device sizes have been shrunk to nanometer scale, the consumer electronics, like the laptop and mobile devices, have been designed to be much smaller than ever. Without suitable protection devices, the functions of these electronics could be reset or even damaged under electrostatic discharge (ESD) events. Currently, all consumer electronics are expected to pass the ESD test requirement of IEC 61000-4-2 standard. Transient voltage suppressor (TVS) is generally designed to bypass the ESD energy, so that the electronic systems can be prevented from ESD damages.

The working principle of transient voltage suppression (TVS) device is shown in FIG. 1. In FIG. 1, a TVS device 10 is connected in parallel with a protected circuit 12 on the printed circuit board (PCB). The transient voltage suppression device 10 would be triggered immediately when the ESD event occurs. In that way, the transient voltage suppression device 10 can provide a superiorly low resistance path for discharging the transient ESD current, so that the energy of the ESD transient current can be bypassed by the transient voltage suppression device 10. The U.S. Pat. No. 8,542,470 B2 disclosed a transient voltage suppressor (TVS) array that includes a trigger diode integrated with an NPN bipolar junction transistor and a PNP bipolar junction transistor forming a silicon-controlled rectifier (SCR). However, the trigger diode is formed in the discharging path of the SCR, increasing the trigger voltage, the turn-on resistance, and the clamping voltage of the SCR. The collector of the NPN bipolar junction transistor is formed in the discharging path of the SCR, increasing the trigger voltage, the turn-on resistance, and the clamping voltage of the SCR. The base of the PNP bipolar junction transistor is coupled to a high voltage, increasing the trigger voltage and the clamping voltage of the SCR.

To overcome the abovementioned problems, the present invention provides an electrostatic discharge protection device, so as to solve the afore-mentioned problems of the prior art.

### SUMMARY OF THE INVENTION

The present invention provides an electrostatic discharge protection device, which decreases the trigger voltage of a silicon-controlled rectifier. In addition, the clamping voltage and the turn-on resistance of the silicon-controlled rectifier can be reduced when a high electrostatic discharge current flows through the silicon-controlled rectifier.

In an embodiment of the present invention, an electrostatic discharge protection device includes a triggering bipolar junction transistor and a silicon-controlled rectifier. The triggering bipolar junction transistor, coupled between a first conduction pad and a second conduction pad, has a first parasitic base-emitter resistance. The silicon-controlled rectifier, coupled between the first conduction pad and the second conduction pad, includes a first parasitic bipolar junction transistor and a second parasitic bipolar junction transistor. The emitter and the base of the second parasitic bipolar junction transistor are respectively coupled to the emitter and the base of the triggering bipolar junction transistor. The second parasitic bipolar junction transistor has a second parasitic base-emitter resistance less than the first parasitic base-emitter resistance. The collector of the triggering bipolar junction transistor is implemented with a first heavily doped area. The base of the first parasitic bipolar junction transistor is implemented with a first doped region that separates from the first heavily doped area. The first doped region and the first heavily doped area have the same conductivity type.

In an embodiment of the present invention, the base of the first parasitic bipolar junction transistor is electrically floating.

In an embodiment of the present invention, the collector and the emitter of the triggering bipolar junction transistor are respectively coupled to the first conduction pad and the second conduction pad.

In an embodiment of the present invention, the emitter of the first parasitic bipolar junction transistor and the emitter of the second parasitic bipolar junction transistor are respectively coupled to the first conduction pad and the second conduction pad.

In an embodiment of the present invention, the triggering bipolar junction transistor and the second parasitic bipolar junction transistor are NPN bipolar junction transistors and the first parasitic bipolar junction transistor is a PNP bipolar junction transistor.

In an embodiment of the present invention, the triggering bipolar junction transistor and the second parasitic bipolar junction transistor are PNP bipolar junction transistors and the first parasitic bipolar junction transistor is an NPN bipolar junction transistor.

In an embodiment of the present invention, the first doped region and the first heavily doped area have a first conductivity type. The base and the emitter of the triggering bipolar junction transistor are respectively implemented with a second doped region that has a second conductivity type opposite to the first conductivity type and a second heavily-doped area that has the first conductivity type. The first heavily doped area and the second heavily-doped area are formed in the second doped region. The emitter and the collector of the first parasitic bipolar junction transistor are respectively implemented with a third heavily-doped area that has the second conductivity type and a third doped region that has the second conductivity type. The first doped region is directly adjacent to the third doped region. The third heavily-doped area is formed in the first doped region. The first heavily-doped area and the third heavily-doped area are coupled to the first conduction pad. The third doped region is directly adjacent to the second doped region. The base and the emitter of the second parasitic bipolar junction transistor are respectively implemented with the third doped region and a fourth heavily-doped area that has the first conductivity type. The fourth heavily-doped area and a fifth heavily-doped area that has the second conductivity type are formed in the third doped region. The second heavily-doped area separates from the fifth heavily-doped area. The second heavily-doped area, the fourth heavily-doped area, and the fifth heavily-doped area are coupled to the second conduction pad.

In an embodiment of the present invention, the doping concentration of the second doped region is less than or equal to that of the third doped region and the shortest distance between the fourth heavily-doped area and the fifth heavily-doped area is less than the shortest distance between the second heavily-doped area and the fifth heavily-doped area.

In an embodiment of the present invention, the doping concentration of the second doped region is less than that of the third doped region and the shortest distance between the fourth heavily-doped area and the fifth heavily-doped area is less than or equal to the shortest distance between the second heavily-doped area and the fifth heavily-doped area.

In an embodiment of the present invention, when a positive electrostatic discharge voltage is applied on the first conduction pad and the second conduction pad is grounded, the triggering bipolar junction transistor, the second parasitic bipolar junction transistor, and the first parasitic bipolar junction transistor are sequentially turned on.

To sum up, the electrostatic discharge protection device arranges the collector of the triggering bipolar junction transistor that separates from the discharging path of the silicon-controlled rectifier to reduce a distance between the anode and the cathode of the silicon-controlled rectifier, thereby decreasing the trigger voltage of the silicon-controlled rectifier. In addition, the clamping voltage and the turn-on resistance of the silicon-controlled rectifier can be reduced when a high electrostatic discharge current flows through the silicon-controlled rectifier.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating a conventional transient voltage suppression (TVS) device;

FIG. 2 is a schematic diagram illustrating an electrostatic discharge protection device according to a first embodiment of the present invention;

FIG. 3 is a schematic diagram illustrating the circuit layout of the electrostatic discharge protection device of FIG. 2;

FIG. 4 is a schematic diagram illustrating the current-voltage curves of an electrostatic discharge protection device according to an embodiment of the present invention;

FIG. 5 is a schematic diagram illustrating an electrostatic discharge protection device according to a second embodiment of the present invention; and

FIG. 6 is a schematic diagram illustrating the circuit layout of the electrostatic discharge protection device of FIG. 5.

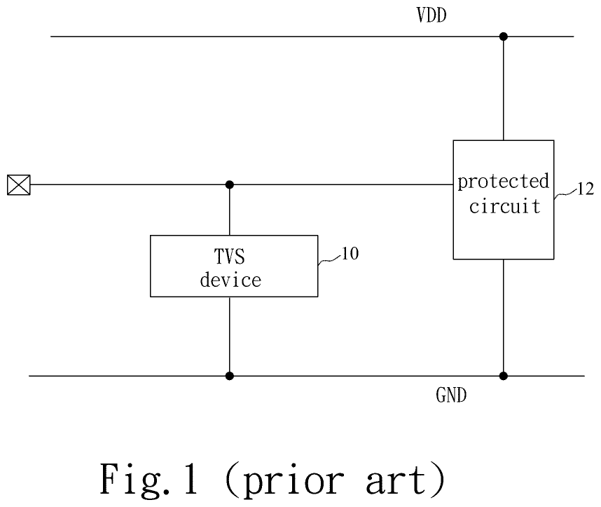

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Certain terms are used throughout the description and the claims to refer to particular components. One skilled in the art appreciates that a component may be referred to using different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

Throughout the description and claims, it will be understood that when a component is referred to as being “positioned on,” “positioned above,” “connected to,” “engaged with,” or “coupled with” another component, it can be directly on, directly connected to, or directly engaged with the other component, or intervening component may be present. In contrast, when a component is referred to as being “directly on,” “directly connected to,” or “directly engaged with” another component, there are no intervening components present.

In the following description, an electrostatic discharge (ESD) protection will be provided, which arranges the collector of a triggering bipolar junction transistor that separates from the discharging path of a silicon-controlled rectifier to reduce a distance between the anode and the cathode of the silicon-controlled rectifier, thereby decreasing the trigger voltage of the silicon-controlled rectifier. In addition, the clamping voltage and the turn-on resistance of the silicon-controlled rectifier can be reduced when a high electrostatic discharge current flows through the silicon-controlled rectifier.

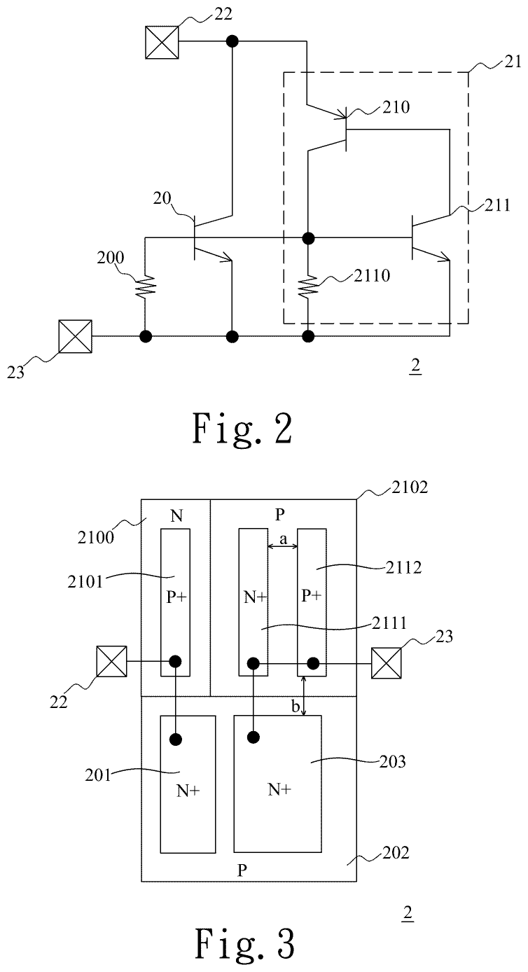

FIG. 2 is a schematic diagram illustrating an electrostatic discharge protection device according to a first embodiment of the present invention. FIG. 3 is a schematic diagram illustrating the circuit layout of the electrostatic discharge protection device of FIG. 2. Referring to FIG. 2 and FIG. 3, the first embodiment of an electrostatic discharge protection device 2 will be introduced as follows. The electrostatic discharge protection device 2 includes a triggering bipolar junction transistor (BJT) 20 and a silicon-controlled rectifier (SCR) 21. The triggering bipolar junction transistor 20, coupled between a first conduction pad 22 and a second conduction pad 23, has a first parasitic base-emitter resistance 200. In some embodiments of the present invention, the collector and the emitter of the triggering bipolar junction transistor 20 are respectively coupled to the first conduction pad 22 and the second conduction pad 23. The silicon-controlled rectifier 21, coupled between the first conduction pad 22 and the second conduction pad 23, includes a first parasitic bipolar junction transistor 210 and a second parasitic bipolar junction transistor 211. The emitter and the base of the second parasitic bipolar junction transistor 211 are respectively coupled to the emitter and the base of the triggering bipolar junction transistor 20. The emitter of the first parasitic bipolar junction transistor 210 and the emitter of the second parasitic bipolar junction transistor 211 are respectively coupled to the first conduction pad 22 and the second conduction pad 23. The second parasitic bipolar junction transistor 211 has a second parasitic base-emitter resistance 2110 less than the first parasitic base-emitter resistance 200. The collector of the triggering bipolar junction transistor 20 is implemented with a first heavily doped area 201. The base of the first parasitic bipolar junction transistor 210 is implemented with a first doped region 2100 that separates from the first heavily doped area 201. The first doped region 2100 and the first heavily doped area 201 have the same conductivity type. In some embodiments of the present invention, the base of the first parasitic bipolar junction transistor 210 may be electrically floating. In the first embodiment, the triggering bipolar junction transistor 20 and the second parasitic bipolar junction transistor 211 are NPN bipolar junction transistors and the first parasitic bipolar junction transistor 210 is a PNP bipolar junction transistor.

Because the second parasitic base-emitter resistance 2110 is less than the first parasitic base-emitter resistance 200, the trigger voltage of the triggering bipolar junction transistor 20 is less than that of the second parasitic bipolar junction transistor 211. Furthermore, the trigger voltage of the triggering bipolar junction transistor 20 is less than that of the silicon-controlled rectifier 21. Thus, the triggering bipolar junction transistor 20 and the silicon-controlled rectifier 21 are sequentially turned on when a positive electrostatic discharge voltage is applied on the first conduction pad 22 while the second conduction pad 23 is grounded. The first parasitic bipolar junction transistor 210 is driven by the second parasitic bipolar junction transistor 211. Accordingly, when the positive electrostatic discharge voltage is applied on the first conduction pad 22 while the second conduction pad 23 is grounded, the triggering bipolar junction transistor 20, the second parasitic bipolar junction transistor 211, and the first parasitic bipolar junction transistor 210 are sequentially turned on. In addition, the base of the first parasitic bipolar junction transistor 210 is electrically floating rather than coupled to a high voltage, such that the trigger voltage of the silicon-controlled rectifier 21 can be reduced, and the clamping voltage and the turn-on resistance of the silicon-controlled rectifier 21 can be reduced when a high electrostatic discharge current flows through the silicon-controlled rectifier 21.

In some embodiments of the present invention, the first doped region 2100 and the first heavily doped area 201 have a first conductivity type. The base and the emitter of the triggering bipolar junction transistor 20 are respectively implemented with a second doped region 202 that has a second conductivity type opposite to the first conductivity type and a second heavily-doped area 203 that has the first conductivity type. In the first embodiment, the first conductivity type is an N type and the second conductivity type is a P type. The first heavily doped area 201 and the second heavily-doped area 203 are formed in the second doped region 202. The emitter and the collector of the first parasitic bipolar junction transistor 210 are respectively implemented with a third heavily-doped area 2101 that has the second conductivity type and a third doped region 2102 that has the second conductivity type. The first doped region 2100 may be directly adjacent to the third doped region 2102. That is to say, there is nothing between the first doped region 2100 and the third doped region 2102. The third heavily-doped area 2101 is formed in the first doped region 2100. The first heavily-doped area 201 and the third heavily-doped area 2101 are coupled to the first conduction pad 22. The third doped region 2102 may be directly adjacent to the second doped region 202. That is to say, there is nothing between the third doped region 2102 and the second doped region 202. The base and the emitter of the second parasitic bipolar junction transistor 211 are respectively implemented with the third doped region 2102 and a fourth heavily-doped area 2111 that has the first conductivity type. The fourth heavily-doped area 2111 and a fifth heavily-doped area 2112 that has the second conductivity type are formed in the third doped region 2102. The second heavily-doped area 203 separates from the fifth heavily-doped area 2112. The second heavily-doped area 203, the fourth heavily-doped area 2111, and the fifth heavily-doped area 2112 are coupled to the second conduction pad 23. The first conduction pad 22 and the second conduction pad 23 are respectively used as the anode and the cathode of the silicon-controlled rectifier 21. When the positive electrostatic discharge voltage is applied on the first conduction pad 22 while the second conduction pad 23 is grounded, an electrostatic discharge current sequentially flows through the third heavily-doped area 2101, the first doped region 2100, the third doped region 2102, and the fourth heavily-doped area 2111. In other words, the first heavily-doped area 201 is not formed in the discharging path of the silicon-controlled rectifier 21. As a result, the electrostatic discharge protection device 2 arranges the collector of the triggering bipolar junction transistor 20 that separates from the discharging path of the silicon-controlled rectifier 21 to reduce a distance between the anode and the cathode of the silicon-controlled rectifier 21, thereby decreasing the trigger voltage of the silicon-controlled rectifier 21. In addition, the clamping voltage and the turn-on resistance of the silicon-controlled rectifier 21 can be reduced when a high electrostatic discharge current flows through the silicon-controlled rectifier 21.

The locations and the doping concentrations of the doped areas and the doped regions need to be adjusted, such that the second parasitic base-emitter resistance 2110 is less than the first parasitic base-emitter resistance 200. In some embodiments of the present invention, the doping concentration of the second doped region 202 is less than or equal to that of the third doped region 2102 and the shortest distance “a” between the fourth heavily-doped area 2111 and the fifth heavily-doped area 2112 is less than the shortest distance “b” between the second heavily-doped area 203 and the fifth heavily-doped area 2112. Alternatively, the doping concentration of the second doped region 202 is less than that of the third doped region 2102 and the shortest distance “a” between the fourth heavily-doped area 2111 and the fifth heavily-doped area 2112 is less than or equal to the shortest distance “b” between the second heavily-doped area 203 and the fifth heavily-doped area 2112. The shortest distance “a” between the fourth heavily-doped area 2111 and the fifth heavily-doped area 2112 is equal to 0 or greater than 0.

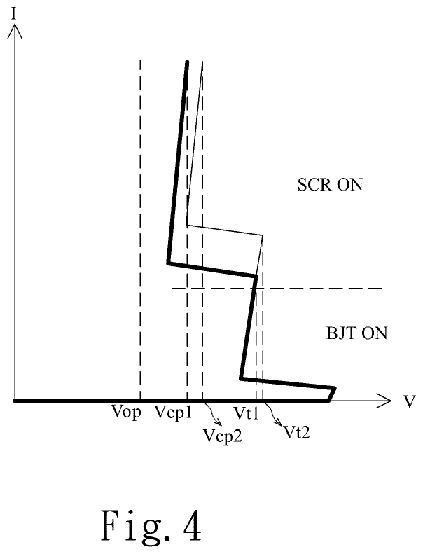

FIG. 4 is a schematic diagram illustrating the current-voltage curves of an electrostatic discharge protection device according to an embodiment of the present invention. Referring to FIG. 2 and FIG. 3, two curves represent the current-voltage characteristics of two electrostatic discharge protection devices 2 are shown in FIG. 4. The curves under a horizontal dotted line represent that the triggering bipolar junction transistor 20 is turned on. The curves above the horizontal dotted line represent that the silicon-controlled rectifier 21 is turned on. A thin solid curve represents the second parasitic base-emitter resistance 2110 is lower than the second parasitic base-emitter resistance 2110 corresponding to a thick solid curve. The trigger voltage Vt1 of the silicon-controlled rectifier 21 is lower than the trigger voltage Vt2 of the silicon-controlled rectifier 21. The clamping voltage Vcp1 of the silicon-controlled rectifier 21 is lower than the clamping voltage Vcp2 of the silicon-controlled rectifier 21. Accordingly, the trigger voltage of the silicon-controlled rectifier 21 can be reduced by adjusting the second parasitic base-emitter resistance 2110 and the first parasitic base-emitter resistance 200. In addition, the silicon-controlled rectifier 21 has the lower clamping voltage when a high electrostatic discharge current flows through the silicon-controlled rectifier 21. The holding voltage of the silicon-controlled rectifier 21 that is changed by adjusting the second parasitic base-emitter resistance 2110 is applied to the variable operating voltage Vop of a protected device. In order to avoid the latch-up issue, the holding voltage of the silicon-controlled rectifier 21 should be greater than the variable operating voltage Vop.

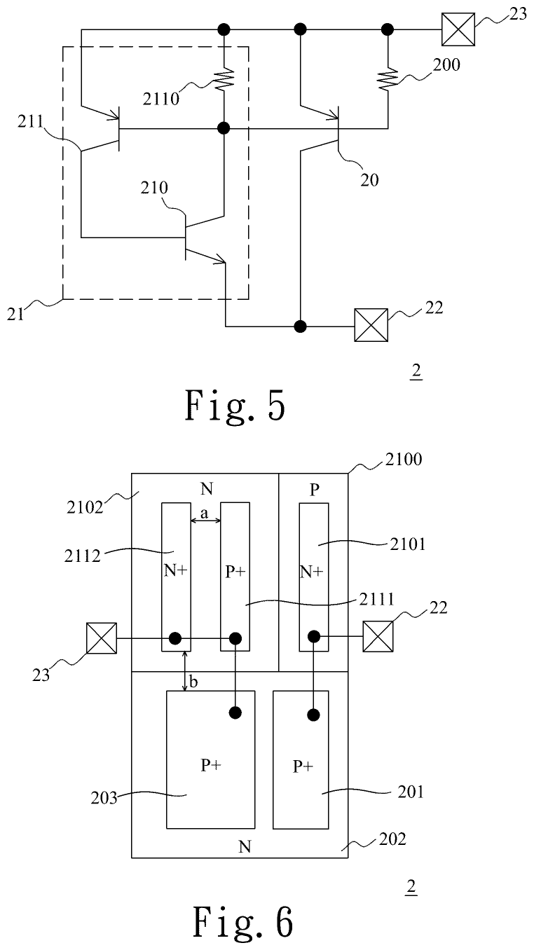

FIG. 5 is a schematic diagram illustrating an electrostatic discharge protection device according to a second embodiment of the present invention. FIG. 6 is a schematic diagram illustrating the circuit layout of the electrostatic discharge protection device of FIG. 5. Referring to FIG. 5 and FIG. 6, the first embodiment is different from the second embodiment in the conductivity type. In the second embodiment, the first conductivity type is a P type and the second conductivity type is an N type. As a result, the triggering bipolar junction transistor 20 and the second parasitic bipolar junction transistor 211 are PNP bipolar junction transistors and the first parasitic bipolar junction transistor 210 is an NPN bipolar junction transistor. The first conduction pad 22 and the second conduction pad 23 are respectively used as the cathode and the anode of the silicon-controlled rectifier 21. The other features have been described previously so it will not be reiterated.

According to the embodiments provided above, the electrostatic discharge protection device arranges the collector of the triggering bipolar junction transistor that separates from the discharging path of the silicon-controlled rectifier to reduce a distance between the anode and the cathode of the silicon-controlled rectifier, thereby decreasing the trigger voltage of the silicon-controlled rectifier. In addition, the clamping voltage and the turn-on resistance of the silicon-controlled rectifier can be reduced when a high electrostatic discharge current flows through the silicon-controlled rectifier.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. An electrostatic discharge protection device comprising:
a triggering bipolar junction transistor, coupled between a first conduction pad and a second conduction pad, having a first parasitic base-emitter resistance; and
a silicon-controlled rectifier, coupled between the first conduction pad and the second conduction pad, comprising a first parasitic bipolar junction transistor and a second parasitic bipolar junction transistor, wherein a base and a collector of the first parasitic bipolar junction transistor are respectively coupled to a collector and a base of the second parasitic bipolar junction transistor, an emitter and the base of the second parasitic bipolar junction transistor are respectively coupled to an emitter and a base of the triggering bipolar junction transistor, and the second parasitic bipolar junction transistor has a second parasitic base-emitter resistance less than the first parasitic base-emitter resistance;
wherein a collector of the triggering bipolar junction transistor is implemented with a first heavily doped area, the base of the first parasitic bipolar junction transistor is implemented with a first doped region that separates from the first heavily doped area, and the first doped region and the first heavily doped area have a same conductivity type.

2. The electrostatic discharge protection device according to claim 1, wherein the base of the first parasitic bipolar junction transistor is electrically floating.

3. The electrostatic discharge protection device according to claim 1, wherein the collector and the emitter of the triggering bipolar junction transistor are respectively coupled to the first conduction pad and the second conduction pad.

4. The electrostatic discharge protection device according to claim 1, wherein an emitter of the first parasitic bipolar junction transistor and the emitter of the second parasitic bipolar junction transistor are respectively coupled to the first conduction pad and the second conduction pad.

5. The electrostatic discharge protection device according to claim 1, wherein the triggering bipolar junction transistor and the second parasitic bipolar junction transistor are NPN bipolar junction transistors and the first parasitic bipolar junction transistor is a PNP bipolar junction transistor.

6. The electrostatic discharge protection device according to claim 1, wherein the triggering bipolar junction transistor and the second parasitic bipolar junction transistor are PNP bipolar junction transistors and the first parasitic bipolar junction transistor is an NPN bipolar junction transistor.

7. The electrostatic discharge protection device according to claim 1, wherein the first doped region and the first heavily doped area have a first conductivity type, the base and the emitter of the triggering bipolar junction transistor are respectively implemented with a second doped region that has a second conductivity type opposite to the first conductivity type and a second heavily-doped area that has the first conductivity type, the first heavily doped area and the second heavily-doped area are formed in the second doped region, an emitter and a collector of the first parasitic bipolar junction transistor are respectively implemented with a third heavily-doped area that has the second conductivity type and a third doped region that has the second conductivity type, the first doped region is directly adjacent to the third doped region, the third heavily-doped area is formed in the first doped region, the first heavily-doped area and the third heavily-doped area are coupled to the first conduction pad, the third doped region is directly adjacent to the second doped region, the base and the emitter of the second parasitic bipolar junction transistor are respectively implemented with the third doped region and a fourth heavily-doped area that has the first conductivity type, the fourth heavily-doped area and a fifth heavily-doped area that has the second conductivity type are formed in the third doped region, the second heavily-doped area separates from the fifth heavily-doped area, and the second heavily-doped area, the fourth heavily-doped area, and the fifth heavily-doped area are coupled to the second conduction pad.

8. The electrostatic discharge protection device according to claim 7, wherein a doping concentration of the second doped region is less than or equal to that of the third doped region and a shortest distance between the fourth heavily-doped area and the fifth heavily-doped area is less than a shortest distance between the second heavily-doped area and the fifth heavily-doped area.

9. The electrostatic discharge protection device according to claim 7, wherein a doping concentration of the second doped region is less than that of the third doped region and a shortest distance between the fourth heavily-doped area and the fifth heavily-doped area is less than or equal to a shortest distance between the second heavily-doped area and the fifth heavily-doped area.

10. The electrostatic discharge protection device according to claim 1, wherein when a positive electrostatic discharge voltage is applied on the first conduction pad and the second conduction pad is grounded, the triggering bipolar junction transistor, the second parasitic bipolar junction transistor, and the first parasitic bipolar junction transistor are sequentially turned on.
